(19) United States
(12) Patent Application Publication
(10) Pub. No.: US 2026/0153807 A1
(43) Pub. Date: Jun. 4, 2026

(54) METHOD FOR REDUCING THE RESOLUTION OF AN AERIAL IMAGE OF A PHOTOLITHOGRAPHY MASK WITHOUT REDUCING A SIGNAL-TO-NOISE RATIO AND CORRESPONDING OPTICAL SYSTEM

(71) Applicant: Carl Zeiss SMT GmbH, Oberkochen (DE)

(72) Inventors: Martin Van Driel, Muenchen (DE); Julian Ott, Aalen (DE)

(21) Appl. No.: 19/400,360

(22) Filed: Nov. 25, 2025

(30) Foreign Application Priority Data
Dec. 1, 2024 (DE) 102024135546.8

(51) Int. Cl. G03F 7/00

(52) U.S. Cl. CPC G03F 7/70325; G03F 7/70666; G03F 7/706837

(57) ABSTRACT

The invention relates to an optical system and a method for reducing the resolution of an aerial image of a photolithography mask without reducing a signal-to-noise ratio, the method comprising: acquiring an aerial image of the photolithography mask using an optical system, in which structures of the photolithography mask are illuminated by a light source and projected onto an image sensor of a camera by use of projection optics, thereby generating an aerial image, wherein a pixel size of the image sensor of the camera is below a Nyquist limit defined by the resolution limit of the optical system; applying an anti-aliasing filter to the acquired aerial image; and downsampling the filtered aerial image to obtain an aerial image of reduced resolution.

### CROSS-REFERENCE TO RELATED APPLICATION

This application claims benefit of German patent application 10 2024 135 546.8, filed on Dec. 1, 2024, which is hereby incorporated by reference in its entirety.

### TECHNICAL FIELD

The invention relates to systems and methods for reducing the resolution of an aerial image in order to reduce the amount of data being processed or saved, but without reducing a signal-to-noise ratio. Thus, the quality of the data remains the same for subsequent processing tasks. The method and system can be used when saving or processing aerial images, in particular as a preliminary step for defect detection or process control.

### BACKGROUND

Semiconductor manufacturing involves precise manipulation, e.g., etching, of materials such as silicon or oxide at very fine scales in the range of nm. Therefore, a quality management process is important for ensuring high quality standards of the manufactured wafers.

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. One of the most crucial steps is the photolithography process.

Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate.

Due to the growing integration density in the semiconductor industry, photolithography masks have to image increasingly smaller structures onto wafers. The production process of photolithographic masks and templates for nanoimprint photolithography is, therefore, becoming increasingly more complex and, as a result, more time-consuming and ultimately also more expensive. With the advent of EUV photolithography scanners, the nature of masks changed from transmission-based to reflection-based patterning.

Each defect in the photolithography mask can lead to unwanted behavior of the produced wafer, or a wafer can be significantly damaged. Therefore, each defect must be found and repaired if possible and necessary. Reliable and fast defect detection methods are, therefore, important for photolithography masks.

In order to analyze photolithography masks for defects, aerial images are commonly used, e.g., in mask inspection systems. An aerial image indicates the radiation intensity distribution of a photolithography system in a wafer plane for a given photolithography mask. The aerial image, thus, simulates the structures on the surface of a wafer after printing without actually having to print a wafer.

Aerial images are typically noisy. The noise can comprise, for example, electronic, optical or photon noise. The pixel size of an image sensor of a camera of an inspection system is driven by two competing factors: the pixel size has to be smaller than the optical resolution limit of the projection optics of the optical system to avoid aliasing and to obtain high signal-to-noise ratios. In fact, even smaller pixels may further improve a signal-to-noise ratio. However, the amount of data increases with the resolution of the aerial image leading to increasing storage and processing costs. Methods for reducing the resolution of an aerial image usually rely on downsampling methods such as binning that reduce the resolution of the aerial image but at the same time a signal-to-noise ratio, in particular close to the Nyquist limit defined by the resolution limit of the optical system. A lower signal-to-noise ratio means information loss that leads to results of lower quality in further processing steps, e.g., in defect detection, and/or to a reduced throughput of the mask inspection system.

Therefore, it is an aspect of the invention to reduce the resolution of an aerial image without reducing a signal-to-noise ratio.

The aspects are achieved by the invention specified in the independent claims. Advantageous embodiments and further developments of the invention are specified in the dependent claims.

### SUMMARY

Embodiments of the invention concern methods and systems for reducing the resolution and, thus, the amount of data, of an aerial image without reducing a signal-to-noise ratio.

A first embodiment involves a method for reducing the resolution of an aerial image of a photolithography mask without reducing a signal-to-noise ratio, the method comprising: acquiring an aerial image of the photolithography mask using an optical system, in which structures of the photolithography mask are illuminated by an illumination optical unit and projected onto an image sensor of a camera by use of projection optics, thereby generating an aerial image, wherein a pixel size of the image sensor of the camera is below a Nyquist limit defined by the resolution limit of the optical system; applying an anti-aliasing filter to the acquired aerial image; and downsampling the filtered aerial image to obtain an aerial image of reduced resolution.

A Nyquist limit refers to a maximum pixel size of the image sensor of the camera such that the maximum signal frequency defined by the resolution limit of the optical system can still be represented in the aerial image without aliasing.

A signal-to-noise ratio (SNR) of an aerial image refers to a ratio of the power of the image signal with respect to the power of image noise. It measures the quality of a signal.

The invention is based on the idea that downsampling such as binning aliases frequencies of the signal above a Nyquist/2 frequency into the lower frequency part of the signal such that the noise amplitude in the binned image remains constant, whereas the signal amplitude is reduced. Thus, the signal-to-noise ratio is reduced, in particular close to the Nyquist limit. Instead, the inventors propose to oversample the aerial image by using a pixel size of the camera below the Nyquist limit and to apply an anti-aliasing filter before downsampling. In this way, the frequencies above the Nyquist/2 frequency are removed instead of being aliased into the lower part of the signal such that the noise amplitude is reduced together with the signal amplitude and the signal-to-noise ratio remains constant, even close to the Nyquist limit.

The combination of oversampling, anti-aliasing and downsampling achieves
a higher SNR than a camera that directly uses the final pixel size, or that uses binning for reducing the resolution to the final pixel size
the same SNR as the original aerial image despite reducing the resolution.

An aerial image indicates the radiation intensity distribution of a photolithography system in a wafer plane for a given photolithography mask. It refers to the image that is formed by the projection of light, e.g., of EUV or DUV wavelength, through a photolithography mask onto an imaging sensor, e.g., charge coupled device (CCD) or complementary metal oxide semiconductor (CMOS) arrays. The aerial image, thus, simulates the structures on the surface of a wafer when printing the wafer using the photolithography mask in the photolithography system. A wafer plane refers to a plane within the resist on top of the wafer in the photolithography system. The imaging sensor can be part of a camera adapted for acquiring images at predetermined wavelengths. The camera can be an EUV camera, and/or a camera comprising a time delay and integration (TDI) sensor. In preferred embodiments, an image acquisition method comprises the use of an EUV camera comprising a TDI sensor. The camera's image sensor can accordingly be an EUV image sensor, i.e., an image sensor that is sensitive to EUV light. EUV light is light in the extreme ultraviolet spectral range with wavelengths between 5 nm and 100 nm, in particular with wavelengths between 5 nm and 30 nm. Especially the EUV light can have a wavelength of 13.5 nm. The EUV camera can be adapted for use in a photolithography mask inspection system, wherein the photolithography mask is projected onto an EUV image sensor of the EUV camera. In preferred embodiments, the image acquisition method comprises illuminating a photolithography mask with actinic radiation within the EUV wavelength range. EUV radiation reflected from the mask is then projected on an imaging sensor of an EUV camera via accordingly adapted projection optics.

An aerial image can, for example, be generated by applying an optical system to a photolithography mask. An aerial image can also be simulated using a design of a photolithography mask and an aerial image simulation method.

The aerial image of the photolithography mask can be acquired by the optical system using light of an actinic wavelength. Mask inspection using light of an actinic wavelength means that the light used for the inspection is of the same wavelength as during the photolithography process.

An aerial image can refer to the aerial image of a complete photolithography mask, or it can refer to the aerial image of a section of the photolithography mask.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

An optical system refers to a system that uses light to obtain an image of a photolithography mask. Optical systems comprise, for example, mask inspection systems, mask qualification systems and metrology systems.

A mask inspection system refers to an optical system used to detect defects in a photolithography mask by acquiring an aerial image of the photolithography mask.

A mask qualification system refers to a system that is used to acquire an aerial image of a portion of a photolithography mask, in particular of potential defects detected using a mask inspection system. The mask qualification system emulates settings of a photolithography system, e.g., illumination and imaging parameters, to examine the effect of a potential defect on a printed wafer, to verify that photolithography masks are defect-free or whether a repair attempt has been successful.

Parameters describing an optical system comprise, for example,
illumination parameters describing the illumination setting of the photolithography system, comprising the distribution and intensities of different illumination angles, e.g., an annular illumination setting, a dipole illumination setting, a quasar illumination setting, etc.,
imaging parameters such as the numerical aperture of the photolithography system and the magnification of the photolithography system, obscurations, aberrations, apodizations or distortions,
design parameters such as parameters describing the material of the photolithography mask, e.g., layer thicknesses, refractive indices of different layers, etc.

An optical system comprises a camera including an image sensor to acquire the aerial image. The image sensor comprises pixels. The pixels can be square pixels, or they can have a rectangular (anisotropic) shape.

An anti-aliasing restricts the bandwidth of a signal to satisfy the Nyquist-Shannon sampling theorem. An anti-aliasing filter is designed such that it minimally disturbs the aerial image in the pass-band (i.e., frequencies below the resolution limit of the optical system) and suppresses noise otherwise. Anti-aliasing filters include low-pass filters and band-pass filters.

Downsampling refers to methods for reducing the resolution of an aerial image.

According to an example, the Nyquist limit is defined with respect to a numerical aperture NA of the projection optics of the optical system and a wavelength A of the illumination provided by the illumination optical unit. In particular, the pixel size of the image sensor of the camera is selected lower or equal to

$$\frac{λ}{4 NA} .$$

In this way, the maximum pixel size of the image sensor can be directly derived from the parameters of the optical system.

In an example, the pixel size of the image sensor of the camera, in particular in a scan direction of the optical system, is less than half of the Nyquist limit. In this way, small details of the photolithography mask can be imaged, and the resolution of the aerial image can still be reduced without reducing the SNR.

In an example, the optical system is a scanning system using a TDI-scanning approach. The optical system scans the photolithography mask in a scan direction that corresponds to the direction of movement of the TDI sensor. The scan direction and the cross-scan direction span a plane that corresponds to the plane of the photolithography mask. The cross-scan direction is orthogonal to the scan direction.

The Nyquist limit can be approximated using an upper bound. In this way, the Nyquist limit is valid for all angles of illumination impinging on the sensor.

According to an example, the anti-aliasing filter is obtained by solving an optimization problem that minimizes the deviation of the frequency response of the anti-aliasing filter from an ideal anti-aliasing filter that suppresses all frequencies above the Nyquist frequency of the optical system and passes all frequencies below unperturbed. In this way, aliasing of high frequency noise into lower frequencies is prevented with respect to some optimality criterion, since the ideal filter is difficult to implement due to a convolution with a kernel with infinite support.

In an example, the anti-aliasing filter is a finite impulse response filter. Such a filter can be easily implemented using field programmable gate arrays (FPGAs) and can, thus, be used to process a real-time data stream received by the camera of the optical system during scanning. In addition, the anti-aliasing filter can be designed to maintain symmetry and avoid image shift by selecting real-valued and symmetric filter coefficients.

In an example, the frequency response of the anti-aliasing filter is derived from a pupil function of the optical system. In this way, the anti-aliasing filter is well adapted to the optical system and achieves a high quality of the aerial image.

According to an aspect of the first embodiment, the filter response of the anti-aliasing filter is selected with respect to a smallest feature size in the aerial image. In this way, it is ensured that all features are imaged accurately in the aerial image. Furthermore, the image size can be reduced even further if the frequency corresponding to the smallest feature size is below the Nyquist frequency.

In an example, the smallest feature size in the aerial image is computed from a simulated aerial image that is simulated from a design of the photolithography mask. In this way, the smallest feature size can be determined a priori, and the filter response of the anti-aliasing filter can then be selected with respect to this smallest feature size. In case the frequency corresponding to the smallest feature size is below the Nyquist frequency, the image size can be reduced.

The pixel size of the acquired aerial image and/or of the filtered aerial image and/or of the downsampled aerial image can be anisotropic. Anisotropic means that the pixel size in scan direction is different from the pixel size in cross-scan direction. Alternatively or in addition, the size of the aerial image can be anisotropic, which means that the number of pixels in scan direction differs from the number of pixels in cross-scan direction. In this way, the resolution of the aerial image can be adapted depending on the direction, e.g., depending on the importance of a direction for further processing of the aerial image.

According to an aspect of the first embodiment, the filtered aerial image is downsampled with a different factor in a scan direction and in a cross-scan direction of the optical system. For example, the filtered aerial image is downsampled only in a scan direction. In this way, the resolution of the aerial image can also be adapted to the direction.

In an example, the anti-aliasing filter is applied to the aerial image only in a scan direction or only in a cross-scan direction of the optical system. In this way, the processing time of the method can be reduced.

In an example, the anti-aliasing filter and the downsampling are implemented as a single operation. In this way, the processing time of the method is reduced.

The application of the anti-aliasing filter and the downsampling of the filtered aerial image can be carried out by a processor of the camera, when acquiring the aerial image in order to reduce required random access memory, or when writing the aerial image to a file in order to reduce required permanent memory. In this way, random access memory and/or permanent memory as well as processing time is saved.

In an example, the method further comprises reconstructing the acquired aerial image at the original resolution without high frequency noise from the downsampled aerial image. In this way, the high frequency noise can be removed from the image and, thus, the SNR is increased.

According to an aspect of the invention, the method further comprises detecting defects in the downsampled aerial image. As the SNR remains the same despite downsampling, defects can be detected from the aerial image of lower resolution just as well as from the aerial image of original resolution. At the same time, required memory and processing time is reduced.

In an example, the method further comprises controlling at least one photolithography mask manufacturing process parameter based on one or more measurements obtained from the downsampled aerial image.

An optical system according to a second embodiment of the invention comprises: an illumination optical unit for illuminating a photolithography mask; a camera comprising an image sensor; projection optics configured to project structures of the photolithography mask illuminated by the illumination optical unit onto the image sensor of the camera to generate an aerial image; one or more processing devices; and one or more machine-readable hardware storage devices comprising instructions that are executable by one or more processing devices to perform operations comprising the method according to the first embodiment of the invention.

The invention described by examples and embodiments is not limited to the embodiments and examples but can be implemented by those skilled in the art by various combinations or modifications thereof.

### DESCRIPTION OF DRAWINGS

FIG. 1 illustrates an exemplary transmission-based optical system, e.g., a deep ultraviolet (DUV) optical system;

FIG. 2 illustrates an exemplary reflection-based optical system, e.g., an extreme ultra-violet light (EUV) optical system;

FIGS. 3A to 3C illustrate the downsampling operation of binning in different directions;

FIG. 4 illustrates the effect of binning as a linear filter in the frequency domain;

FIG. 5 illustrates the effect of binning on a signal-to-noise ratio of the aerial image;

FIG. 6 illustrates an ideal anti-aliasing filter and an approximation by use of an FIR filter;

FIG. 7 is a flowchart of the method for reducing the resolution of an aerial image of a photolithography mask without reducing a signal-to-noise ratio according to a first embodiment of the invention;

FIG. 8 illustrates the computation of a maximum pixel size of an image sensor of a camera of an EUV inspection system;

FIGS. 9A to 9D illustrate the advantages of the method according to the first embodiment of the invention for defect detection.

### DETAILED DESCRIPTION

In the following, advantageous exemplary embodiments of the invention are described and schematically shown in the figures. Throughout the figures and the description, same reference numbers are used to describe same features or components.

The methods and systems herein can be used with a variety of optical systems, e.g., transmission-based optical systems 10 or reflection-based optical systems 10′ such as EUV systems.

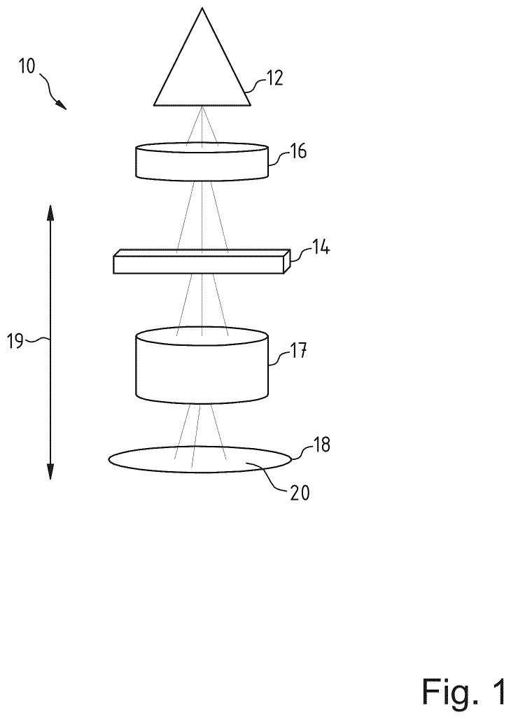

FIG. 1 illustrates an exemplary transmission-based optical system 10, e.g., a DUV photolithography system. Major components are a light source 12, which may be a deep-ultraviolet (DUV) excimer laser source, imaging optics which, for example, define the partial coherence and which may include optics that shape radiation from the light source 12, a photolithography mask 14, illumination optics 16 that illuminate the photolithography mask 14 and projection optics 17 that project an image of the photolithography mask design onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(θₘₐₓ), wherein n is the refractive index of the media between the substrate and the last element of the projection optics 17, and θₘₐₓ is the largest angle of the beam exiting from the projection optics 17 that can still impinge on the wafer plane 18. The radiation distribution at the wafer plane 18 is imaged by an image sensor 20 of a camera to generate an aerial image.

In the present document, the terms “illumination”, “radiation” or “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 3-100 nm).

Illumination optics 16 may include optical components for shaping, adjusting and/or projecting radiation from the light source 12 before the radiation passes the photolithography mask 14. Projection optics 17 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 17 may comprise various types of optical systems, including refractive optics, reflective optics, apertures and catadioptric optics, for example. Illumination optics 16 and projection optics 17 may also include components operating according to any of these design types for directing, shaping or controlling the projection beam of radiation, collectively or singularly.

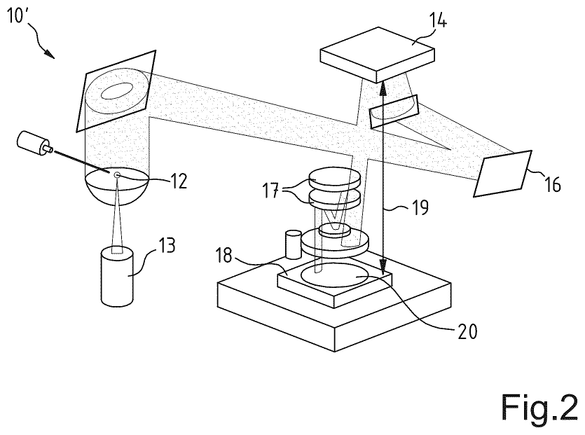

FIG. 2 illustrates an exemplary reflection-based optical system 10′, e.g., an extreme ultraviolet light (EUV) lithography system. Major components are a light source 12 in the form of an EUV plasma source that is ignited by an IR-laser 13, illumination optics 16 which, for example, define the partial coherence and which may include optics that shape radiation from the light source 12, a photolithography mask 14, and projection optics 17 that project an image of the photolithography mask design onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(θₘₐₓ), wherein n is the refractive index of the media between the substrate and the last element of the projection optics 17, and θₘₐₓ is the largest angle of the beam exiting from the projection optics 17 that can still impinge on the wafer plane 18. The radiation distribution at the wafer plane 18 is imaged by an image sensor 20 of a camera to generate an aerial image.

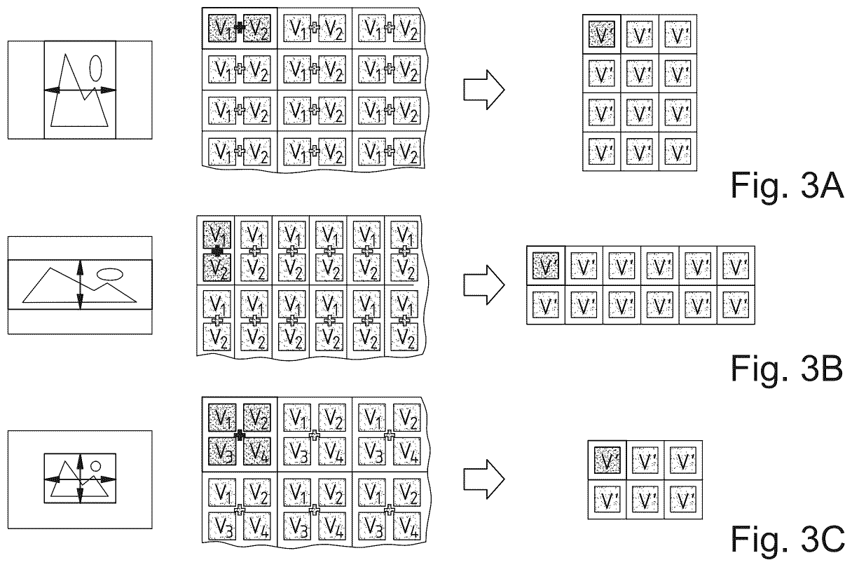

An optical system 10, 10′, e.g., a mask inspection system, a mask qualification system or a metrology system such as the ones shown in FIGS. 1 and 2, can be used to generate an aerial image of the photolithography mask. The pixel size of the image sensor 20 of the inspection system 10, 10′ is selected at least below the optical resolution limit of the projection optics 17 to avoid aliasing. Even lower pixel sizes can further improve the SNR of the generated aerial image. However, lower pixel sizes increase the amount of data required for storing or processing the aerial image, thereby increasing computation time, required resources and costs. The resolution of an aerial image can be reduced, for example, by using downsampling methods such as binning as illustrated in FIGS. 3A to 3C.

FIGS. 3A to 3C show binning applied to the pixels of an image in horizontal direction in FIG. 3A, in vertical direction in FIG. 3B and in both horizontal and vertical directions in FIG. 3C. Binning is an operation that replaces two or more pixels by a single one and by computing the value of the single pixel from the values of the original pixels, e.g., by computing the average of the two or more pixels (averaging binning) or by computing the sum of the two or more pixels (additive binning). For example, in horizontal direction as indicated in FIG. 3A binning can be described by the following equation:

$${I}_{ij}^{b} = \frac{{I}_{i ( 2 j )} + {I}_{i ( 2 j + 1 )}}{2}$$

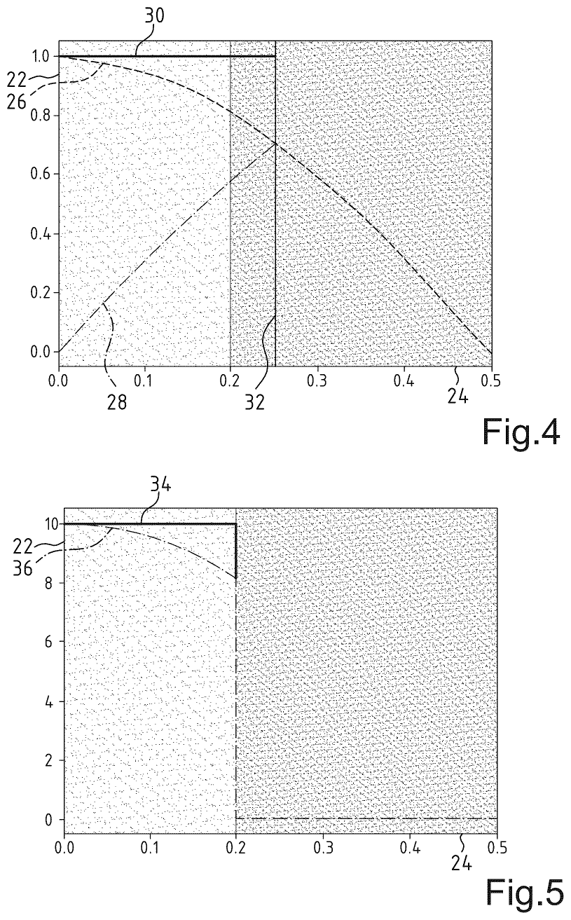

FIG. 4 illustrates the effect of binning as a linear filter in the frequency domain. The horizontal axis 24 indicates frequency with the unit measure 1/px, the vertical axis 22 indicates the corresponding amplitude. This example assumes a resolution of 2.5 times the Nyquist limit of the image sensor 20 of the camera. Thus, frequencies below 0.2/px contain an image signal and noise, whereas frequencies above 0.2/px only contain noise.

The binning operation above can be rewritten as a discrete convolution with a kernel containing the sum of two delta functions:

$$K ( x ) = \frac{δ ( x ) + δ ( x + Δ )}{2}$$

where Δ means a distance of one pixel.

In the frequency domain this kernel is equivalent to a cosine function with a phase shift:

$$\tilde{K} ( f ) = F \{ K ( x ) \} = exp ( i πΔ f ) \frac{exp ( i πΔ f ) + exp ( - i πΔ f )}{2} = exp ( i πΔ f ) cos ( πΔ f )$$

Thus, the absolute is proportional to cos(πΔf). The amplitude of the frequencies is, therefore, reduced by a cosine filter 26.

Subsequently, the aerial image is downsampled by preserving only every second pixel. In this way, the resolution of the aerial image is reduced by a factor of 2, and, thus, the new Nyquist limit after binning 32 is 0.25/px. The downsampling aliases the remaining energy above half the new Nyquist limit after binning 32 into the low frequency part with an amplitude proportional to cos(π(0.5−Δf))=sin(πΔf). This binning alias 28 is statistically independent of the long period part of the noise. Assuming white noise with an amplitude of 1 in the original aerial image, the binned noise amplitude 30 in the binned aerial image is, thus,

$$\sqrt{{cos}^{2} ( πΔ f ) + {sin}^{2} ( πΔ f )} = 1$$

Therefore, the noise in spectral domain is still white and at the same amplitude. As the amplitude of the signal is reduced by a cosine factor, whereas the noise amplitude remains the same, the SNR of the signal is reduced. The effect is stronger the closer the frequency is to the Nyquist limit.

FIG. 5 shows an example from the EUV domain. For a mask inspection system for EUV photolithography masks the maximum frequency of the signal is about 0.2 of the original sampling frequency in scan direction. Here, again, the frequencies up to 0.2/px contain signal and noise, whereas the frequencies above 0.2/px contain only noise. As shown with respect to FIG. 4, binning reduces the signal amplitude, whereas the noise amplitude remains the same. Therefore, the signal after binning 36 drops up to about 20% when approaching the Nyquist limit compared to an assumed signal 34 of 1 before binning.

Therefore, it is an aspect of the invention to reduce the resolution of a generated aerial image in an optical system without decreasing the SNR. The reason for the lower SNR after binning is that binning does not completely reduce the high frequencies and, thus, creates the binning alias 28 in the frequency range of the signal as shown in FIG. 4.

The binning alias 28 can be reduced by applying an anti-aliasing filter to the aerial image before downsampling, in order to remove the frequencies above the Nyquist limit. In this way, the SNR remains unaffected. An ideal anti-aliasing filter 38 would perfectly remove all frequencies above the Nyquist frequency 42. As Fast Fourier Transforms cannot be used in a continuous data stream, approximations are required.

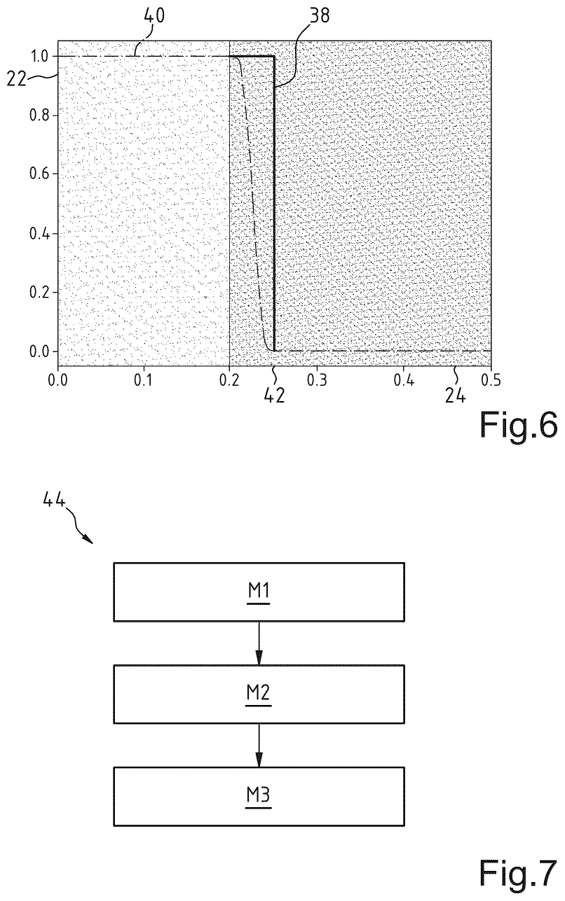

According to an example, the anti-aliasing filter is obtained by solving an optimization problem that minimizes the deviation of the frequency response of the anti-aliasing filter from an ideal anti-aliasing filter 38 that suppresses all frequencies above the Nyquist frequency 42 of the optical system 10, 10′ and passes all frequencies below unperturbed. For example, a finite impulse response (FIR) filter 40 (in this case with 128 taps) can be used as an approximation of an ideal anti-aliasing filter 38 as illustrated in FIG. 6. The optimization problem can, for example, comprise to find an FIR filter by solving a least squares optimization or by using a minimax criterion and the Remez algorithm.

The anti-aliasing filter can, for example, be implemented using a Fourier transform of the aerial image and a frequency domain description of the filter response function of the anti-aliasing filter.

In an example, the anti-aliasing filter is applied to the aerial image only in a scan direction or only in a cross-scan direction of the optical system 10, 10′.

In alternative example, the anti-aliasing filter is applied simultaneously in a scan direction and in a cross-scan direction of the optical system 10, 10′. The filter response function is, thus, a function of two coordinates. The application of the anti-aliasing filter then corresponds to a convolution with a 2D filter kernel. In this way, the processing time of the method is reduced.

After applying an anti-aliasing filter to the aerial image, the filtered aerial image is downsampled. Downsampling refers to the reduction of pixels in the aerial image. Operations can be applied to the original aerial image to reduce the information loss. For example, selecting every n-th pixel from the aerial image, or binning as explained with respect to FIG. 3, are downsampling operations. The filtered aerial image can be downsampled with a different factor in a scan direction and in a cross-scan direction of the optical system. For example, the filtered aerial image can be downsampled only in a scan direction.

Therefore, by applying oversampling (maximum pixel size of the image sensor 20 is below the Nyquist limit) to an aerial image followed by applying an anti-aliasing filter and downsampling of the signal, the resolution of the aerial image is reduced without reducing the SNR. At the same time, the SNR is increased with respect to cameras that directly use the number of pixels after downsampling when acquiring the aerial image, or with respect to cameras that use binning to reduce the number of pixels.

A flowchart of the method 44 for reducing the resolution of an aerial image of a photolithography mask 14 without reducing a signal-to-noise ratio according to a first embodiment of the invention is illustrated in FIG. 7. It comprises the following steps: acquiring an aerial image of the photolithography mask 14 using an optical system 10, 10′, in which structures of the photolithography mask 14 are illuminated by a light source 12 and projected onto an image sensor 20 of a camera by use of projection optics 17, thereby generating an aerial image, wherein the maximum pixel size of the image sensor 20 of the camera is below a Nyquist limit defined by the resolution limit of the optical system 10, 10′ in a step M1; applying an anti-aliasing filter to the acquired aerial image in a step M2; and downsampling the filtered aerial image to obtain an aerial image of reduced resolution in a step M3.

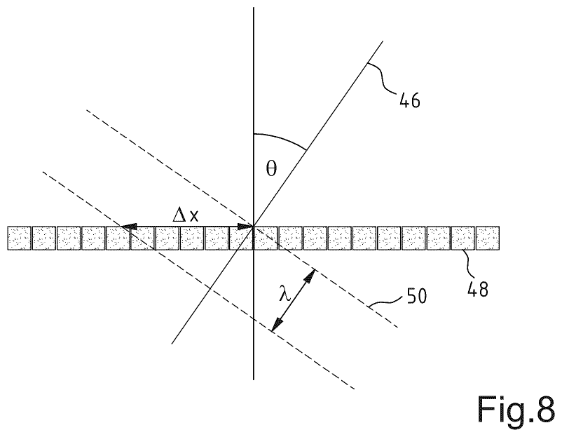

As shown in FIG. 2, the maximum pixel size Δxₘₐₓ can be derived as explained in the following with respect to FIG. 8. The incoming light 46 from the imaging pupil is impinging on the image sensor 20 at a maximum angle θ. The wavefronts of the corresponding electromagnetic field 50 with wavelength λ are indicated by dashed lines. The shortest horizontal wavelength of the electromagnetic field 50 on the image sensor 20 can be obtained from the maximum angle θ of the incoming light 46 impinging on the image sensor 20:

$$sin θ \leq \frac{λ}{Δ x} .$$

$$It follows$$

$$Δ x \leq \frac{λ}{NA}$$

Here, NA refers to the numerical aperture of the projection optics 17 of the optical system 10, 10′ and is defined as NA=sin θ. As the image sensor 20 is sensitive to intensity, i.e., to the square of the electromagnetic field 50, the relevant scale length of the signal is smaller by an additional factor of 2. The Nyquist sampling requirement is half the scale length. Thus, the required maximum pixel size is

$$Δ x \leq \frac{λ}{4 NA}$$

This is a theoretical upper bound. In practice, this upper bound may be relaxed.

In case of an EUV mask inspection system, a NA of, for example, 0.25 can be assumed in a cross-scan direction that is orthogonal to a scan direction of the optical system 10, 10′ and a wavelength of 13.5 nm. The corresponding theoretical upper bound of the maximum pixel size is then 13.5 nm in cross-scan direction. A NA of 0.125 in scan direction leads to a corresponding theoretical upper bound of the maximum pixel size of 27 nm. The current optical design of EUV mask inspection systems uses a pixel size of, e.g., 10 nm. This means oversampling by a factor of

$$\frac{13.5 nm}{10 nm} = 1.35$$

in cross-scan direction and by a factor of

$$\frac{27 nm}{10 nm} = 2.7$$

in scan direction. Thus, in the current optical design of EUV mask inspection systems, the images are oversampled by a factor>2 in scan direction. Thus, the pixel size of the image sensor 20 of the camera in a scan direction of the optical system 10′ is less than half of the Nyquist limit. The application of an anti-aliasing filter to the oversampled aerial image followed by a downsampling, e.g., removing every second pixel, achieves 1) a higher SNR than a camera that directly uses the final pixel size or binning, 2) the same SNR for the reduced resolution as with the full resolution.

Apart from FIR anti-aliasing filters, other anti-aliasing filters can be designed.

In an example, the frequency response of the anti-aliasing filter is derived from a pupil function of the optical system by filtering in the scan direction according to the NA-derived resolution limit. The pupil is a function in frequency space that is not 0 exactly where the optical system allows light to pass through. So, the corresponding filter would be 1 where the pupil is not equal to 0 and 0 otherwise.

In an example, the filter response of the anti-aliasing filter is selected with respect to a smallest feature size in the aerial image. The smallest feature size can be computed from the acquired aerial image, e.g., using the highest frequency of the spectrum of the aerial image, or using image processing methods such as segmentation, object detection or pattern matching methods, or using machine learning methods. A machine learning model such as a deep learning model can, for example, be trained to measure the smallest feature size in an aerial image. To this end, aerial images with corresponding smallest feature size values can be used as training data. The machine learning model then learns from the training data which features are useful in order to identify the smallest feature size in the aerial image.

The smallest feature size in the aerial image can also be computed from a simulated aerial image that is simulated from a design of the photolithography mask.

A design of a photolithography mask refers to a representation of the photolithography mask or a section thereof. The design can, for example, comprise a computer readable file, such as a CAD file or a GDS file, or a technical drawing, a set of polygons representing the structures of the photolithography mask or a section thereof. A design of a photolithography mask can comprise material information, e.g., complex refractive indices of materials contained in the photolithography mask, electric permittivities, magnetic permeabilities, or derived representations. A design of a photolithography mask can comprise descriptions of the structures within the photolithography mask, e.g., in the form of curves, contours, polygons, Splines, NURBS, Bézier curves, etc. A design can refer to the design of a complete photolithography mask, or it can refer to the design of a section of the photolithography mask.

An aerial image simulation method simulates an aerial image of a photolithography mask from a design of the photolithography mask. It can comprise the use of a physical model. It can also comprise the use of a machine learning model for learning a mapping from a design to an aerial image or for learning a part of this mapping. Among the aerial image simulation methods, there are rigorous simulation methods such as finite difference time domain (FDTD) or rigorous coupled wave analysis (RCWA) that are known to a person skilled in the art. Since they require long computation times, fast approximations such as the thin element approximation (TEA) can be used. The thin element approximation (TEA) assumes that the thickness of the structures on the photolithography mask is very small compared to the wavelength of the incoming light, and that the widths of the structures on the photolithography mask are very large compared to the wavelength. However, as photolithographic processes use radiation of shorter and shorter wavelengths, and the structures on the photolithography mask become smaller and smaller, these assumptions do not hold anymore, and mask 3D effects must be taken into account. Therefore, the results of the TEA method are less accurate but much faster to obtain than rigorous simulation results. To obtain fast and accurate results, simulation methods that are based on physical models but still do not rely on the thin mask assumption can be used, e.g., the one disclosed in PCT application No. PCT/EP2023/087651 or in German patent application No. 10 2022 135019.3, the entire contents of the above applications are herein incorporated by reference.

Given a design of a photolithography mask, e.g., in a CAD format, a simulated aerial image can be computed from the design using an aerial image simulation method such as the ones mentioned before.

In an example, the pixel size of the acquired aerial image and/or of the filtered aerial image and/or of the downsampled aerial image is anisotropic. Thus, before or after each step of the method 44 according to the first embodiment of the invention, the pixel size of the aerial image can be anisotropic, i.e., different in a scan direction and in a cross-scan direction.

When applying the anti-aliasing filter and the downsampling successively, a lot of values are computed by the anti-aliasing filter that are removed by the downsampling. To prevent these unnecessary operations, the values of the downsampled aerial image are directly computed within a single operation. Thus, according to an aspect of the invention, the anti-aliasing filter and the downsampling are implemented as a single operation.

In an example, the application of the anti-aliasing filter and the downsampling of the filtered aerial image are carried out by a processor of the camera, when acquiring the aerial image in order to reduce required random access memory, or when writing the aerial image to a file in order to reduce required permanent memory. In this way, random access memory and/or permanent memory requirements are reduced.

The method can further comprise modifying, e.g., increasing, the resolution of the downsampled aerial image to obtain an aerial image without high frequency noise at a higher resolution. In particular, the method can further comprise reconstructing the acquired aerial image at the original resolution without high frequency noise from the downsampled aerial image. The reconstructed aerial image without high frequency noise but with the same SNR can be used for further processing, e.g., for defect detection. In this way, further processing operations can be applied to the reconstructed image without modification, e.g., machine learning models do not have to be retrained, since the resolution of the reconstructed aerial image remains the same.

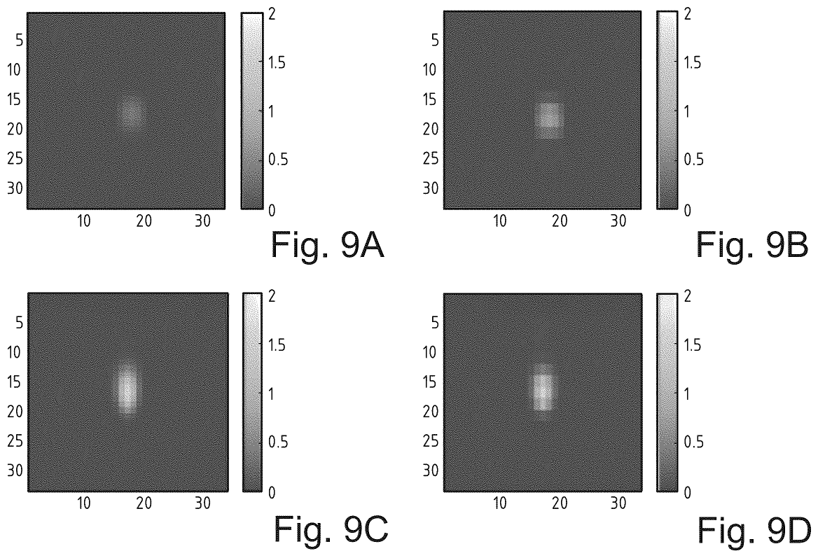

The method can further comprise detecting defects in the downsampled aerial image. As the SNR is the same as in the original aerial image, the defect detection results will be of the same quality, but with a lower resolution (and, thus, data rate) of the aerial image, as for example illustrated in FIGS. 9A to 9D below.

Defects can be detected using any of various defect detection methods known to a person skilled in the art, e.g., image processing methods such as segmentation, object detection, pattern matching methods. Alternatively, machine learning models for defect detection can be trained using training data, e.g., sample aerial images with and without defects and corresponding defect indicators such as a “defect/no defect” indicator, bounding boxes or a binary segmentation of a defect, etc. In addition to a single aerial image, one or more reference aerial images that are usually defect-free and show a comparable section of a photolithography mask can be used to compare the acquired aerial image to in order to derive information on defects from the differences.

FIGS. 9A to 9D illustrate the advantages of the method according to the invention for defect detection. FIGS. 9A and 9B show difference images of an aerial image containing a defect and a reference image without defect, FIG. 9A for an image sensor 20 with full resolution and FIG. 9B after anti-aliasing filtering and downsampling (in this case binning) for an image sensor of half the resolution in each direction. The amplitude of the difference image is comparable or even better in case of the reduced resolution. FIG. 9C and FIG. 9D show heatmaps indicating the corresponding SNR for the images in FIG. 9A and FIG. 9B respectively. The maximum SNR is 1.61 in both images in FIG. 9C and FIG. 9D, showing that the anti-aliasing filtering followed by downsampling does not decrease the SNR.

The method can further comprise controlling at least one photolithography mask manufacturing process parameter based on one or more measurements obtained from the downsampled aerial image. Photolithography mask manufacturing parameters comprise, for example, additional mask repair or particle removal steps. Measurements obtained from the downsampled aerial image comprise, for example, a critical dimension (CD) indicating the minimum feature size in the aerial image.

The invention is not limited to reflection-based optical systems 10′ such as EUV optical systems, in particular EUV mask inspection systems. Corresponding observations also apply to transmission-based optical systems 10.

An optical system, as illustrated in FIGS. 1 and 2, comprises: a light source 12 for illuminating a photolithography mask 14; a camera comprising an image sensor 20; projection optics 17 configured to project structures of the photolithography mask 14 illuminated by the light source 12 onto the image sensor 20 of the camera to generate an aerial image; one or more processing devices; and one or more machine-readable hardware storage devices comprising instructions that are executable by one or more processing devices to perform operations comprising the method for reducing the resolution of an aerial image of a photolithography mask without reducing a signal-to-noise ratio according to the first embodiment described above.

In some implementations, each of the one or more processing devices can include one or more processor cores, and each processor core can include logic circuitry for processing data. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, the one or more processing devices can include one or more computers, each computer can include one or more data processors for processing data. The one or more machine-readable hardware storage devices can store one or more computer programs including instructions that when executed by the one or more computers cause the one or more computers to carry out the processes described above. The one or more processing devices can include one or more input devices, such as a keyboard, a mouse, a touchpad, and/or a voice command input module, and one or more output devices, such as a display, and/or an audio speaker.

In some implementations, the one or more processing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may refer to different embodiments, examples, or aspects. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

Embodiments, examples and aspects of the invention may be described using the following clauses:
1. A method 44 for reducing the resolution of an aerial image of a photolithography mask 14 without reducing a signal-to-noise ratio, the method comprising:
   Acquiring an aerial image of the photolithography mask 14 using an optical system 10, 10′, in which structures of the photolithography mask 14 are illuminated by a light source 12 and projected onto an image sensor 20 of a camera by use of projection optics 17, thereby generating an aerial image, wherein a pixel size of the image sensor 20 of the camera is below a Nyquist limit defined by the resolution limit of the optical system 10, 10′;
   Applying an anti-aliasing filter to the acquired aerial image;
   Downsampling the filtered aerial image to obtain an aerial image of reduced resolution.
2. The method of clause 1, wherein the Nyquist limit is defined with respect to a numerical aperture of the projection optics 17 of the optical system 10, 10′ and a wavelength of the illumination provided by the light source 12.
3. The method of any one of the preceding clauses, wherein a pixel size of the image sensor 20 of the camera is lower or equal to

$$\frac{λ}{4 NA} ,$$

wherein λ refers to a wavelength of the illumination provided by the light source 12 and NA refers to a numerical aperture of the projection optics 17 of the optical system 10, 10′.
4. The method of any one of the preceding clauses, wherein the Nyquist limit is approximated using a lower bound.
5. The method of any one of the preceding clauses, wherein a pixel size of the image sensor 20 of the camera of the optical system 10, 10′ is less than half of the Nyquist limit.
6. The method of clause 5, wherein the pixel size of the image sensor 20 of the camera in a scan direction of the optical system 10, 10′ is less than half of the Nyquist limit.
7. The method of any one of the preceding clauses, wherein the anti-aliasing filter is a finite impulse response filter 40.
8. The method of any one of the preceding clauses, wherein the anti-aliasing filter is obtained by solving an optimization problem that minimizes the deviation of the frequency response of the anti-aliasing filter from an ideal anti-aliasing filter 38 that suppresses all frequencies above the Nyquist frequency of the optical system 10, 10′ and passes all frequencies below unperturbed.
9. The method of any one of the preceding clauses, wherein the frequency response of the anti-aliasing filter is derived from a pupil function of the optical system 10, 10′.
10. The method of any one of the preceding clauses, wherein the filter response of the anti-aliasing filter is selected with respect to a smallest feature size in the aerial image.
11. The method of clause 10, wherein the smallest feature size in the aerial image is computed from a simulated aerial image that is simulated from a design of the photolithography mask.
12. The method of any one of the preceding clauses, wherein the pixel size of the acquired aerial image and/or of the filtered aerial image and/or of the downsampled aerial image is anisotropic.
13. The method of any one of the preceding clauses, wherein the filtered aerial image is downsampled with a different factor in a scan direction and in a cross-scan direction of the optical system 10, 10′.
14. The method of any one of the preceding clauses, wherein the filtered aerial image is downsampled only in a scan direction.
15. The method of any one of the preceding clauses, wherein the anti-aliasing filter is applied to the aerial image only in a scan direction or only in a cross-scan direction of the optical system 10, 10′.
16. The method of any one of the preceding clauses, wherein the anti-aliasing filter and the downsampling are implemented as a single operation.
17. The method of any one of the preceding clauses, wherein the application of the anti-aliasing filter and the downsampling of the filtered aerial image are carried out by a processor of the camera, when acquiring the aerial image in order to reduce required random access memory, or when writing the aerial image to a file in order to reduce required permanent memory.
18. The method of any one of the preceding clauses, further comprising reconstructing the acquired aerial image at the original resolution without high frequency noise from the downsampled aerial image.
19. The method of any one of the preceding clauses, further comprising detecting defects in the downsampled aerial image.
20. The method of any one of the preceding clauses, further comprising controlling at least one photolithography mask manufacturing process parameter based on one or more measurements obtained from the downsampled aerial image.
21. An optical system 10, 10′, comprising:
   a light source 12 for illuminating a photolithography mask 14;
   a camera comprising an image sensor 20;
   projection optics 17 configured to project structures of the photolithography mask 14 illuminated by the light source 12 onto the image sensor 20 of the camera to generate an aerial image;
   one or more processing devices;
   one or more machine-readable hardware storage devices comprising instructions that are executable by one or more processing devices to perform operations comprising the method 44 of any one of the preceding clauses.

In a general aspect, the invention relates to an optical system and a method for reducing the resolution of an aerial image of a photolithography mask 14 without reducing a signal-to-noise ratio, the method comprising: acquiring an aerial image of the photolithography mask 14 using an optical system 10′, in which structures of the photolithography mask 14 are illuminated by a light source 12 and projected onto an image sensor 20 of a camera by use of projection optics 17, thereby generating an aerial image, wherein a pixel size of the image sensor 20 of the camera is below a Nyquist limit defined by the resolution limit of the optical system 10′; applying an anti-aliasing filter to the acquired aerial image; and downsampling the filtered aerial image to obtain an aerial image of reduced resolution.

Reference number list

| | |
|---|---|
| 10, 10′ | Optical system |
| 12 | Light source |
| 13 | IR-laser |
| 14 | Photolithography mask |
| 16 | Illumination optics |
| 17 | Projection optics |
| 18 | Wafer plane |
| 19 | Projection section |
| 20 | Image sensor |
| 22 | Vertical axis |
| 24 | Horizontal axis |
| 26 | Cosine filter |
| 28 | Binning alias |
| 30 | Binned noise amplitude |
| 32 | Nyquist resolution limit after binning |
| 34 | Assumed signal |
| 36 | Signal after binning |
| 38 | Ideal anti-aliasing filter |
| 40 | FIR filter |
| 42 | Nyquist frequency |
| 44 | Method |
| 46 | Incoming light |
| 48 | Image sensor pixels |
| 50 | Wavefronts of electromagnetic field |
| 52 | Horizontal axis |
| 54 | Vertical axis |

What is claimed is:

1. A method for reducing the resolution of an aerial image of a photolithography mask without reducing a signal-to-noise ratio, the method comprising:
acquiring an aerial image of the photolithography mask using an optical system, in which structures of the photolithography mask are illuminated by a light source and projected onto an image sensor of a camera by use of projection optics, thereby generating an aerial image, wherein a pixel size of the image sensor of the camera is below a Nyquist limit defined by the resolution limit of the optical system;
applying an anti-aliasing filter to the acquired aerial image; and
downsampling the filtered aerial image to obtain an aerial image of reduced resolution.

2. The method of claim 1, wherein the Nyquist limit is defined with respect to a numerical aperture of the projection optics of the optical system and a wavelength of the illumination provided by the light source.

3. The method of claim 1, wherein a pixel size of the image sensor of the camera is lower or equal to
$$\frac{λ}{4 NA} ,$$
wherein λ refers to a wavelength of the illumination provided by the light source and NA refers to a numerical aperture of the projection optics of the optical system.

4. The method of claim 1, wherein the Nyquist limit is approximated using an upper bound.

5. The method of claim 1, wherein a pixel size of the image sensor of the camera of the optical system is less than half of the Nyquist limit.

6. The method of claim 5, wherein the pixel size of the image sensor of the camera in a scan direction of the optical system is less than half of the Nyquist limit.

7. The method of claim 1, wherein the anti-aliasing filter is a finite impulse response filter.

8. The method of claim 1, wherein the anti-aliasing filter is obtained by solving an optimization problem that minimizes the deviation of the frequency response of the anti-aliasing filter from an ideal anti-aliasing filter that suppresses all frequencies above the Nyquist frequency of the optical system and passes all frequencies below unperturbed.

9. The method of claim 1, wherein the frequency response of the anti-aliasing filter is derived from a pupil function of the optical system.

10. The method of claim 1, wherein the filter response of the anti-aliasing filter is selected with respect to a smallest feature size in the aerial image.

11. The method of claim 10, wherein the smallest feature size in the aerial image is computed from a simulated aerial image that is simulated from a design of the photolithography mask.

12. The method of claim 1, wherein the pixel size of the acquired aerial image and/or of the filtered aerial image and/or of the downsampled aerial image is anisotropic.

13. The method of claim 1, wherein the filtered aerial image is downsampled with a different factor in a scan direction and in a cross-scan direction of the optical system.

14. The method of claim 1, wherein the filtered aerial image is downsampled only in a scan direction.

15. The method of claim 1, wherein the anti-aliasing filter is applied to the aerial image only in a scan direction or only in a cross-scan direction of the optical system.

16. The method of claim 1, wherein the anti-aliasing filter and the downsampling are implemented as a single operation.

17. The method of claim 1, wherein the application of the anti-aliasing filter and the downsampling of the filtered aerial image are carried out by a processor of the camera, when acquiring the aerial image in order to reduce required random access memory, or when writing the aerial image to a file in order to reduce required permanent memory.

18. The method of claim 1, further comprising reconstructing the acquired aerial image at the original resolution without high frequency noise from the downsampled aerial image.

19. The method of claim 1, further comprising detecting defects in the downsampled aerial image.

20. The method of claim 1, further comprising controlling at least one photolithography mask manufacturing process parameter based on one or more measurements obtained from the downsampled aerial image.

21. An optical system, comprising:
a light source for illuminating a photolithography mask;
a camera comprising an image sensor;
projection optics configured to project structures of the photolithography mask illuminated by the light source onto the image sensor of the camera to generate an aerial image;
one or more processing devices;
one or more machine-readable hardware storage devices comprising instructions that are executable by the one or more processing devices to perform operations comprising the method of claim 1.
